(19) United States
(12) Patent Application Publication
(10) Pub. No.: US 2025/0201721 A1
(43) Pub. Date: Jun. 19, 2025

(54) SUBSTRATE BONDING METHOD AND BONDED SUBSTRATE

(71) Applicant: Tokyo Electron Limited, Tokyo (JP)

(72) Inventors: Motoyuki SATO, Tokyo (JP); Kiyotaka IMAI, Tokyo (JP)

(21) Appl. No.: 19/072,273

(22) Filed: Mar. 6, 2025

Related U.S. Application Data
(63) Continuation of application No. PCT/JP2023/032540, filed on Sep. 6, 2023.

(30) Foreign Application Priority Data
Sep. 20, 2022 (JP) 2022-149457

(51) Int. Cl. H01L 23/538; H01L 23/498; H01L 25/00; H01L 25/065

(52) U.S. Cl. CPC H01L 23/5383; H01L 23/49811; H01L 25/0657; H01L 25/50

(57) ABSTRACT

A substrate bonding method includes: (a) providing two substrates each including wiring portions and a stack portion disposed between the wiring portions, the stack portion including an underlying layer and an upper layer that have etching selectivity in a thickness direction; (b) forming a surface at which the wiring portions and the upper layer are leveled; (c) removing the upper layer while leaving the underlying layer; (d) supplying an adhesive to at least an area, from which the upper layer is removed, to form an adhesive layer having a lower elastic modulus than the underlying layer; (e) forming a bonding surface at which the wiring portions and the adhesive layer are leveled; and (f) arranging the bonding surface of one of the two substrates and the bonding surface of the other substrate to face each other and bonding the two substrates with the adhesive layers, performed in order.

### CROSS-REFERENCE TO RELATED APPLICATIONS

This application is a continuation application of International Application No. PCT/JP2023/032540, filed Sep. 6, 2023, which claims propriety to Japanese Patent Application No. 2022-149457 filed Sep. 20, 2022. The contents of these applications are incorporated herein by reference in their entirety.

### BACKGROUND

### 1. Field of the Invention

The present disclosure relates to substrate bonding methods and bonded substrates.

### 2. Description of the Related Art

There is disclosed a technology of bonding two substrates to each other in a manner such that insulating films (low-K dielectric layers) of the substrates face each other. In such a bonding method, the bonding strength between the substrates is reduced if fine particles are present on the surfaces of the substrate (see, for example, U.S. Pat. No. 6,080,640).

Further, there is disclosed a technology of replacing an interlayer insulating film formed between adjacent wiring portions with an adhesive to bond substrates with the adhesive (see, for example, Japanese Patent Laid-Open Publication No. 2020-520562).

### SUMMARY

According to one aspect, a substrate bonding method for bonding two substrates to each other is provided. The substrate bonding method includes: (a) providing of the two substrates each including wiring portions and a stack portion disposed between the wiring portions, where the stack portion includes an underlying layer and an upper layer that have etching selectivity in a thickness direction; (b) forming of a surface at which the wiring portions and the upper layer are leveled; (c) removing of the upper layer while leaving the underlying layer; (d) supplying of an adhesive to at least an area, from which the upper layer is removed, to form an adhesive layer having a lower elastic modulus than the underlying layer; (e) forming of a bonding surface at which the wiring portions and the adhesive layer are leveled; and (f) arranging of the bonding surface of one of the two substrates and the bonding surface of the other one of the two substrates to face each other and bonding the two substrates with the adhesive layers, wherein (a), (b), (c), (d), (e), and (f) are performed in order as mentioned.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1A is a cross-sectional view schematically illustrating substrates before bonding and a bonding apparatus according to a first embodiment;

FIG. 1B is a cross-sectional view schematically illustrating a bonded substrate;

FIG. 2 is a block diagram illustrating a bonding system;

FIG. 3 is a flowchart illustrating a substrate bonding method;

FIG. 4A is a cross-sectional view schematically illustrating a first leveling step of a precursor substrate by a leveling apparatus;

FIG. 4B is a cross-sectional view schematically illustrating a removal step by a removing apparatus;

FIG. 5A is a flowchart illustrating a conductive-layer-portion forming method;

FIG. 5B is a flowchart illustrating an adhesive application step;

FIG. 6A is a cross-sectional view schematically illustrating an adhesive application step by an adhesive application apparatus;

FIG. 6B is a cross-sectional view schematically illustrating a second leveling step by a leveling apparatus;

FIG. 7A is a cross-sectional view schematically illustrating a precursor substrate and a first leveling step according to the second embodiment;

FIG. 7B is a cross-sectional view schematically illustrating a removal step according to the second embodiment;

FIG. 7C is a cross-sectional view schematically illustrating an adhesive application step according to the second embodiment;

FIG. 7D is a cross-sectional view schematically illustrating a second leveling step according to the second embodiment;

FIG. 8A is a cross-sectional view schematically illustrating a substrate before bonding and a bonding apparatus according to the second embodiment; and

FIG. 8B is a cross-sectional view schematically illustrating a bonded substrate according to the second embodiment.

### DETAILED DESCRIPTION

Embodiments for carrying out the present disclosure will be described with reference to drawings hereinafter. In the drawings, the same constituent components are denoted by the same referential numerals, and redundant description may be omitted.

### First Embodiment

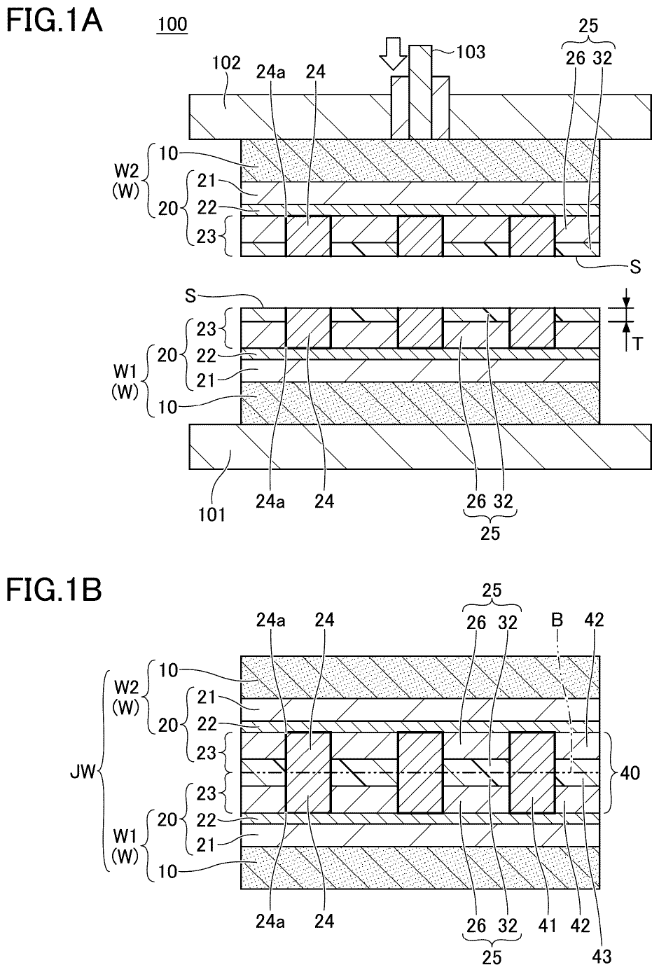

As illustrated in FIG. 1A and FIG. 1B, the substrate bonding method according to the first embodiment of the present disclosure bonds two substrates W to each other using a bonding apparatus 100 to produce one bonded substrate JW. In order to facilitate understanding of the substrate bonding method, a configuration of each substrate W before bonding and a configuration of a bonded substrate JW after bonding in the bonding apparatus 100 will be described hereinafter.

Two substrates W (first substrate W1 and second substrate W2) are formed as circular plates having substantially the same shape (same diameter). Each of the two substrates W before bonding includes a base material 10, in which an appropriate semiconductor device is formed on a silicon wafer, a compound semiconductor wafer, or the like, and a bulk structure 20, in which multiple layers are stacked on the base material 10. As the silicon wafer, single crystal silicon, silicon carbide, a SOI wafer, or the like can be used. As the compound semiconductor wafer, a GaAs wafer, a SiC wafer, a GaN wafer, an InP wafer, or the like can be used. The device of the base material 10 is not particularly limited. Examples of the device include a transistor having a gate, a source, and a drain.

In the bulk structure 20 of the substrate W, a first insulating layer portion 21, a second insulating layer portion 22, and a conductive layer portion 23 are stacked in this order in the direction from the side of the base material 10 toward the surface (from the lower layer to the upper layer). Note that the insulating layer portion of the bulk structure 20 is not limited to two layers (the first insulating layer portion 21 and the second insulating layer portion 22). The insulating layer portion of the bulk structure 20 may include three layers or more, or may be composed of a single layer.

The first insulating layer portion 21 is a bulk insulation film covering the base material 10. As the first insulating layer portion 21, for example, a silicon oxide film (SiO₂ film) can be used. For formation of the SiO₂ film, any known film formation method, such as plasma chemical vapor deposition (CVD), thermal CVD, or the like, can be used.

The second insulating layer portion 22 is formed of an insulating material having a higher dielectric constant than the first insulating layer portion 21. As the second insulating layer portion 22, for example, a silicon nitride film (SiN film) can be used. For formation of the SiN film, any known film formation method, such as plasma CVD, thermal CVD, or the like, can also be used.

The conductive layer portion 23 includes wiring portions 24 formed in an appropriate conductive pattern according to the device of the base material 10, and an insulating stack portion 25 formed between the wiring portions 24. In other words, the wiring portions 24 are formed by forming holes (contact holes) or grooves (trenches) in the insulating stack portion 25, which has been stacked on the second insulating layer portion 22 in advance, in the thickness direction, and filling the holes or grooves with the wiring portions 24, respectively.

The wiring portions 24 are electrically connected to the device of the base material 10, and are formed along the planar direction of the conductive layer portion 23 with gaps between the wiring portions 24. For each wiring portion 24, a metal material having conductivity is used. Examples of the metal material include copper (Cu).

Further, a barrier metal 24a is formed between each wiring portion 24 and the second insulating layer 22 and between each wiring portion 24 and the insulating stack portion 25 in order to inhibit a reaction between the wiring portion 24 and the insulating layer portion. As the barrier metal 24a, for example, titanium nitride (TiN), tantalum nitride (TaN), tungsten nitride (WN), or the like can be used.

The insulating stack portion 25 constitutes an interlayer insulation film that insulates between the adjacent wiring potions 24 in the planar direction of the substrate W with a gap between the adjacent wiring portions 24. Specifically, the insulating stack portion 25 includes an underlying layer 26 stacked on the second insulating layer portion 22, and an adhesive layer 32 stacked on the underlying layer 26.

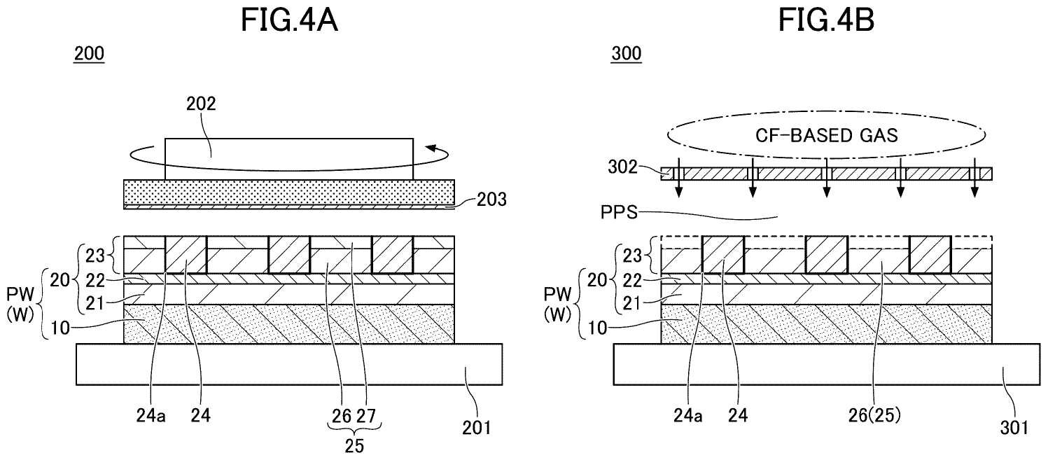

The underlying layer 26 is formed in advance to formation of the conductive layer portion 23 on the surface of the second insulating layer portion 22, thereby constituting a lower layer (base layer) of the insulating stack portion 25. The underlying layer 26 is preferably formed of an insulating material having a low dielectric constant. Although the details will be described later, a material of the underlying layer 26 is selected so that etching selectivity can be sufficiently ensured with respect to the upper layer 27 (see FIG. 4A) stacked on the underlying layer 26 in course of formation of a substrate W before bonding. In the case where the upper layer 27 is formed of a SiO₂ film, for example, as the material of the underlying layer 26, a carbon-doped silicon oxide film (SiOC film), which has a lower dielectric constant than the SiO₂ film and has the resistance against an etching gas of the SiO₂ film, is preferably used.

The adhesive layer 32 is applied onto the underlying layer 26 in the process of the substrate bonding method to thereby constitute a portion that bonds the opposing substrates W together during production of a bonded substrate JW. As the adhesive layer 32, for example, an organic adhesive (organic film) having a high bonding strength (free surface energy) at room temperature and a lower elastic modulus than each wiring portion 24 and the underlying layer 26 is used. A type of the organic adhesive is not particularly limited. An appropriate adhesive can be selected from a thermoplastic resin-based adhesive, a thermoset resin-based adhesive, and an elastomer-based adhesive, considering a bonding strength, an elastic modulus, processability, or the like.

The thickness T of the adhesive layer 32 before bonding is set to be thinner than the thickness of the underlying layer 26. For example, the thickness T of the adhesive layer 32 before bonding is preferably in the approximate range of 20 nm to 150 nm. In the present embodiment, the thickness T of the adhesive layer 32 before bonding is set to 100 nm. When the thickness T of the adhesive layer 32 is less than 20 nm, the bonding strength of the adhesive layer 32 may be reduced. Further, when the thickness T of the adhesive layer 32 is greater than 150 nm, problems may be caused such that the wiring portions 24 are likely to be collapsed, a thermal contraction is increased due to a difference of the thermal expansion coefficient with the wiring portion 24 such that damage, such as cracks or the like, is likely to be caused, gas is likely to be generated from the adhesive layer 32, and the like.

The wiring portions 24 and the adhesive layer 32 of the insulating stack portion 25 constitute an exposed surface (bonding surface S) of each substrate W before bonding. As the bonding surface S of the substrate W is subjected to a leveling step in the substrate bonding method, the wiring portions 24 and the adhesive layer 32 form a flat shape in which the wiring portions 24 and the adhesive layer 32 are continuous to be flush with each other. As described above, the conductive layer portion 23 of the substrate W constitutes a bonding portion that can be bonded to an opposing substrate W.

As illustrated in FIG. 1A and FIG. 1B, the bonded substrate JW is produced by arranging bonding surfaces S of two substrates W to face each other and bonding the conductive layer portions 23 of the two substrates W to each other. Accordingly, the bonded substrate JW has an interface B at which the bonding surfaces S are integrated. At the interface B, for example, the opposing wiring portions 24 are closely adhered to each other, respectively, and the opposing adhesive layers 32 are closely adhered to each other. The adhesive layers 32 are adhered to each other with a high bonding strength so that the entire bonded substrate JW can be securely fixed.

Accordingly, the bonded substrate JW includes the base material 10, the first insulating layer portion 21, the second insulating layer portion 22, the conductive layer portion 23, the conductive layer portion 23, the second insulating layer portion 22, the first insulating layer portion 21, and the base material 10 in order from the first substrate W1 to the second substrate W2. The two conductive layer portions 23, which are integrated in the bonded substrate JW by bonding, may also be collectively referred to as a conductive bonded layer portion 40.

The conductive bonded layer portion 40 includes wiring portions 41 and an insulating stack portion 42 disposed between the wiring portions 41 in a planar direction (direction orthogonal to the thickness direction). The wiring portions 41 are formed by closely adhering the wiring portions 24 of the first substrate W1 and the wiring portions 24 of the second substrate W2 in the thickness direction. The insulating stack portion 42 is formed by closely adhering the insulating stack portion 25 of the first substrate W1 to the insulating stack portion 25 of the second substrate W2 in the thickness direction.

Thus, the insulating stack portion 42 includes a pair of the underlying layers 26, each of which is disposed at a corresponding side of the both sides in the thickness direction, and the adhesive layer 43 interposed between the underlying layers 26. The adhesive layer 43 is a layer in which the adhesive layer 32 of the first substrate W1 and the adhesive layer 32 of the second substrate W2 are bonded and integrated.

In a bonded substrate of the related art, an adhesive layer is not provided at bonding surfaces of two substrates, and the bonding surfaces each including wiring portions and an insulating layer (upper layer 27, see FIG. 4A) are bonded to each other. In this case, bonding strength between the insulating layers is reduced if even a small number of fine particles is present at the bonding surface. Further, in a substrate bonding method of the related art, a plasma treatment is performed to activate an insulating layer of a bonding surface before bonding. Since the plasma treatment is performed, problems, such as reduction of conductivity due to alteration of the wiring portions, increase in current leakage due to scattering of metal of wiring caused by sputtering, and the like, are caused. Further, in the substrate bonding method of the related art, even a slight misalignment in bonding may cause diffusion of a metal, leading to an insulation failure.

Conversely, the bonded substrate JW according to the present embodiment includes the adhesive layer 43, and therefore a high bonding strength can be achieved without performing a plasma treatment. Since the plasma treatment is not performed, diffusion of the metal does not occur, and alteration of the wiring portions 41 does not occur so that excellent conductivity can be assured, and current leakage can be inhibited. Even if some particles are present between the first substrate W1 and the second substrate W2, the bonded substrate JW can inhibit reduction in the bonding strength owing to the elasticity of the adhesive layer 43. Further, the bonded substrate JW can assure the reliability of insulation owing to the adhesive layer 43 having the diffusion resistance of the metal (Cu), even if bonding misalignment occurs.

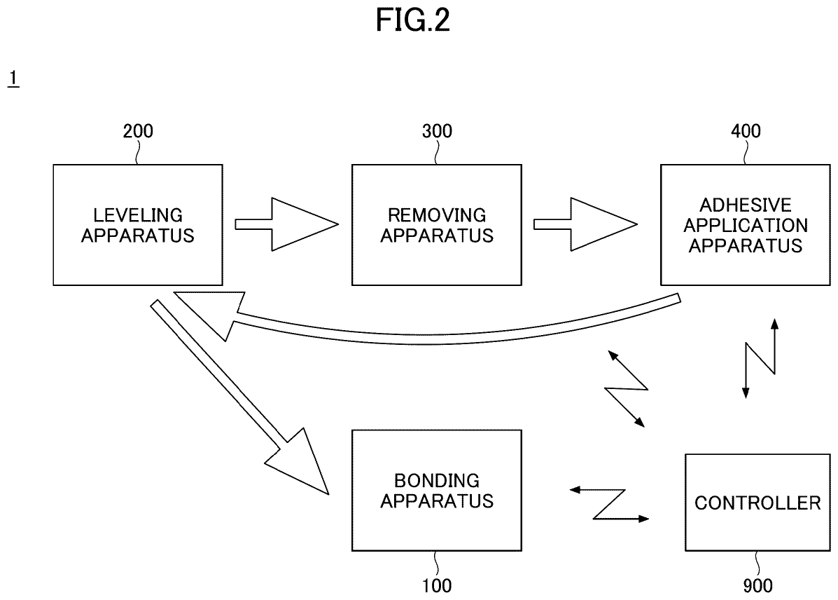

In order to produce the above bonded substrate JW, it is necessary to form two substrates W (see FIG. 1A) each having an adhesive layer 32 in a conductive layer portion 23 before bonding the two substrates W together. Thus, in the substrate bonding method, two substrates W before bonding are formed and the two substrates W are bonded using a bonding system 1 composed of multiple apparatuses, as illustrated in FIG. 2. Note that the bonding system 1 may be composed of multiple apparatuses installed in one production site (a clean room of a factory, etc.) or multiple apparatuses installed in different production sites.

Specifically, the bonding system 1 includes, as apparatuses for forming substrates W before bonding, a leveling apparatus 200, a removing apparatus 300, and an adhesive application apparatus 400, and includes, as an apparatus for bonding two substrates W to each other, a bonding apparatus 100 (see also FIGS. 1A and 1B). The leveling apparatus 200 is an apparatus for leveling a surface of a substrate W. The removing apparatus 300 is an apparatus for removing an upper layer 27 (see FIG. 4A) formed at the surface of the substrate W. The adhesive application apparatus 400 is an apparatus for applying an adhesive onto the surface of the substrate W.

Further, the bonding system 1 includes a controller 900 that controls an operation status of each apparatus, a status of a substrate during the process, and the like. As the controller 900, a computer including a processor, a memory, an input/output interface, and a communication interface, which are not illustrated, is used. The bonding system 1 may be configured as an automated system that automatically produces a bonded substrate JW by synchronizing the above apparatuses, a transport device, which is not illustrated, and the like under control of the controller 900.

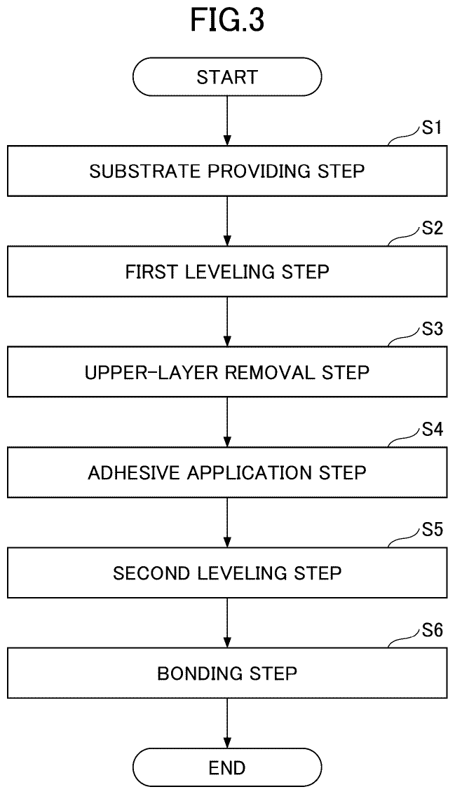

In the substrate bonding method using the above apparatuses of the bonding system 1, multiple steps illustrated in FIG. 3 are sequentially performed. Specifically, the substrate bonding method performs a substrate providing step (step S1), a first leveling step (step S2), an upper-layer removal step (step S3), an adhesive application step (step S4), a second leveling step (step S5), and a bonding step (step S6) in this order.

In the substrate providing step, as illustrated in FIG. 4A, an operator of the bonding system 1 prepares a substrate W before forming an adhesive layer 32 (may be also referred to as a precursor substrate PW hereinafter). The precursor substrate PW includes a base material 10, and a bulk structure 20 in which a first insulating layer portion 21, a second insulating layer portion 22, and a conductive layer portion 23 are stacked.

The conductive layer portion 23 of the precursor substrate PW includes wiring portions 24 and an insulating stack portion 25 formed between the wiring portions 24. The insulating stack portion 25 is composed of multiple layers (an underlying layer 26 and an upper layer 27) with etching selectivity in the thickness direction. As the underlying layer 26, for example, an insulation film having a lower dielectric constant than the upper layer 27 may be used. As an example of such an insulation film, a SiOC film is used.

An insulation film that insulates the wiring portions 24 from one another is also used as the upper layer 27. In the substrate bonding method according to the present embodiment, the upper layer 27 is a layer portion that is removed in the upper-layer removal step, and then replaced with an adhesive layer 32. A material constituting the upper layer 27 is preferably an appropriate material that can ensure etching selectivity with respect to the underlying layer 26. In the present embodiment, a SiO₂ film is used as the material of the upper layer 27 corresponding to the SiOC film of the underlying layer 26.

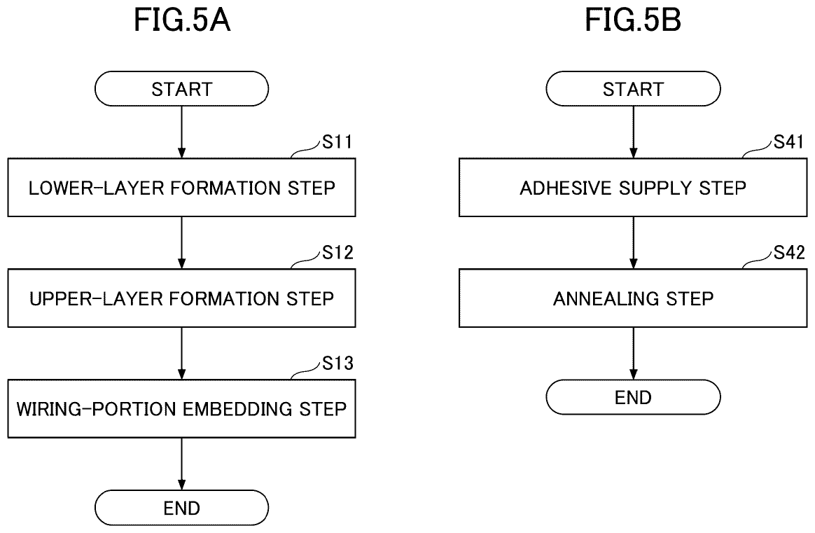

The conductive layer portion 23 of the precursor substrate PW can be formed, for example, by sequentially performing steps of a conductive-layer-portion forming method illustrated in FIG. 5A. In the conductive-layer-portion forming method, first, a lower-layer formation step S11 is performed to stack an underlying layer 26 on the second insulating layer portion 22. In the case where a SiOC film is used as the underlying layer 26, for example, the underlying layer 26 can be formed by plasma CVD in which a source gas including organic siloxane is supplied and plasma is excited.

Next, in the conductive-layer-portion forming method, an upper-layer formation step S12 is performed to stack an upper layer 27 on the formed underlying layer 26. In the case where a SiO₂ film is used as the upper layer 27, for example, the upper layer 27 can be formed by plasma CVD in which a gas including silicon is supplied as a source gas, an oxygen gas or ozone gas is supplied as a reactive gas, and plasma is excited.

Thereafter, in the conductive-layer-portion forming method, a wiring-portion embedding step is performed (step S13). In the wiring-portion embedding step, holes or grooves are formed at predetermined positions of the underlying layer 26 and the upper layer 27, which have been formed in advance, and the formed holes or grooves are filled with a Cu film by electroplating or the like to embed the Cu film into the holes or grooves. When the Cu film is embedded, a thin film of a barrier metal 24a is formed on an exposed surface of the upper layer 27 and an exposed surface of the underlying layer 26, and then a thick Cu film is formed on the barrier metal 24a. As the above steps are performed, the conductive-layer-portion forming method can form a configuration in which the upper layer 27 and the underlying layer 26 are entirely covered with the Cu film constituting the wiring portions 24.

In the substrate bonding method, once the above precursor substrate PW is prepared, a first leveling step (step S2 of FIG. 3) is performed. In the first leveling step, the surface (the surface covered with the Cu film) of the precursor substrate PW is leveled using the leveling apparatus 200 of the bonding system 1 (see FIG. 2).

For example, the leveling apparatus 200 includes, as illustrated in FIG. 4A, a chuck 201 configured to hold the precursor substrate PW, and a rotator 202 that can relatively rotate and move with respect to the precursor substrate PW held by the chuck 201 in a processing chamber that is not illustrated. To an area of the rotator 202 facing the precursor substrate PW, a slurry 203 is provided. The slurry 203 is brought into contact with the Cu film and polishes the Cu film during rotation. The slurry 203 is formed of a material that can level the Cu constituting the wiring portions 24.

Moreover, the leveling apparatus 200 polishes the Cu film by appropriately setting leveling conditions, such as contact pressure of the slurry 203 with respect to the precursor substrate PW, the rotational speed, and the like. During the polishing, the Cu film (including the barrier metal 24a) covering the upper layer 27 is removed to expose the upper layer 27. Therefore, after performing the first leveling step, the surface of the precursor substrate PW is in the state where the upper layer 27 is exposed between the wiring portions 24, and the wiring portions 24 and the upper layer 27 are continuous to be flush (leveled) with each other.

In the substrate bonding method, an upper-layer removal step (step S3 of FIG. 3) is performed after the first leveling step to remove the upper layer 27 while leaving the underlying layer 26, among the layers constituting the conductive layer portion 23. A method of removing the upper layer 27 of the precursor substrate PW is not particularly limited, and examples of the method include dry etching, a method in which a solvent for removal (e.g., hydrofluoric acid) is applied, or the precursor substrate PW is immersed in the solvent, and the like. FIG. 4B illustrates an example of the removing apparatus 300 (etching apparatus) that performs dry etching.

The removing apparatus 300 includes a chuck 301 configured to hold the precursor substrate PW, and a shower portion 302 configured to supply etching gas to the precursor substrate PW held by the chuck 301 in a processing chamber that is not illustrated. As the etching gas, an appropriate gas according to a type of the upper layer 27 to be removed may be used. In the case where the upper layer 27 is a SiO₂ film, for example, a fluorine-based gas, such as CF-based gas or the like, is supplied.

Moreover, the removing apparatus 300 supplies high-frequency power to the shower portion 302 or another electrode, which is not illustrated, to excite plasma in a plasma processing space PPS between the shower portion 302 and the precursor substrate PW. Thus, the CF-based gas formed into the plasma hits the upper layer 27 of the precursor substrate PW, thereby removing the upper layer 27, that is, etching the interlayer insulation film. During the etching, the underlying layer 26, over which the upper layer 27 is selectively etched, remains without being removed by the removing apparatus 300. Since the upper layer 27 is removed as described above, the precursor substrate PW is transformed into the state where the underlying layer 26 is exposed, and the wiring portions 24 are slightly projected from the underlying layer 26. The precursor substrate PW can inhibit collapse or peeling of the wiring portions 24 owing to the underlying layer 26.

The substrate bonding method performs an adhesive application step (step S4 of FIG. 3) after the upper-layer removal step so that an adhesive layer (referred to as a precursor adhesive layer 31 hereinafter), which covers the entire surface of the precursor substrate PW with an adhesive, is formed. In the adhesive application step, the adhesive is supplied to the surface of the precursor substrate PW by the adhesive application apparatus 400 (see FIG. 2).

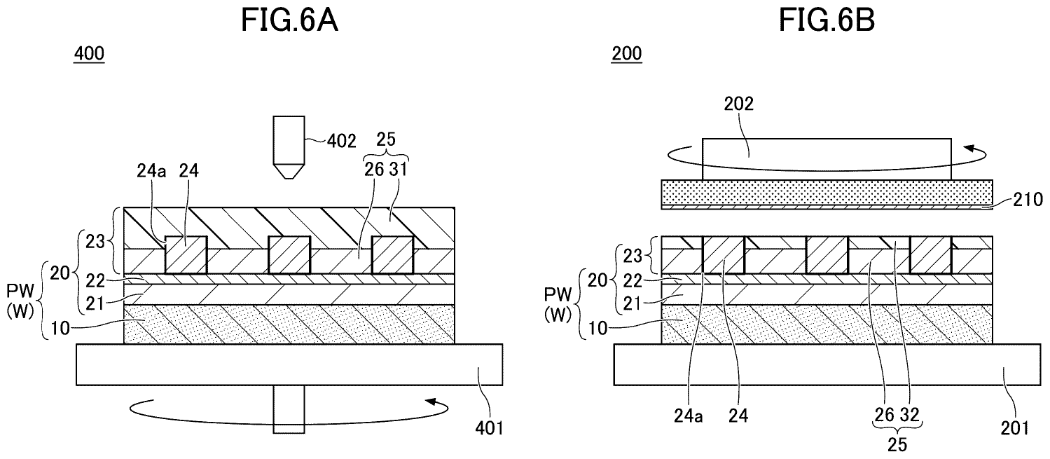

For example, the adhesive application apparatus 400 includes, as illustrated in FIG. 6A, a chuck 401 configured to hold the precursor substrate PW, and a nozzle 402 that ejects an adhesive to the precursor substrate PW held by the chuck 401 in a processing chamber that is not illustrated. Moreover, the chuck 401 has a function of rotating the precursor substrate PW about the center of the chuck 401 by a rotation mechanism that is not illustrated. The nozzle 402 supplies the liquid adhesive from the upper side of the center of the chuck 401 in the vertical direction. Thus, the adhesive application apparatus 400 can guide the adhesive to the entire surface of the precursor substrate PW using the centrifugal force applied during rotation. The adhesive is supplied until the wiring portions 24 and the underlying layer 26 of the precursor substrate PW are entirely covered with the adhesive.

In the adhesive application step, a process of heating the precursor adhesive layer 31 to cure the precursor adhesive layer 31 may be performed after supplying the adhesive. Specifically, as illustrated in FIG. 5B, the adhesive application step includes an adhesive supply step (step S41) in which the adhesive is supplied by the above-described adhesive application apparatus 400, and an annealing step (step S42) in which the adhesive is heated. In the annealing step, the precursor substrate PW including the precursor adhesive layer 31 is placed in a heating device, which is not illustrated, to heat at a target temperature (e.g., an appropriate temperature in the range of 200° C. to 400° C.). Thus, the precursor adhesive layer 31 after the annealing step has a higher elastic modulus than the elastic modulus of the precursor adhesive layer 31 after the adhesive supply step, which facilitates processing performed in a second leveling step. However, since the precursor adhesive layer 31 subjected to the annealing step is an organic film, the precursor adhesive layer 31 after the annealing step has a lower elastic modulus than the elastic modulus of the wiring portion 24 or the elastic modulus of the underlying layer.

The substrate bonding method performs a second leveling step (step S5 of FIG. 3) after the adhesive application step so that the surface of the precursor substrate PW including the precursor adhesive layer 31 is polished, and a bonding surface S including the wiring portions 24 and the adhesive layer 32 is formed. In the second leveling step, leveling can be performed by the leveling apparatus 200 (see FIG. 2), as in the first leveling step. It is needless to say that the bonding system 1 can use a leveling apparatus, which is different from the leveling apparatus 200 used in the first leveling step, in the second leveling step.

As illustrated in FIG. 6B, the leveling apparatus 200 of the second leveling step uses a slurry 210 that is different from the slurry 203 of the first leveling step because a polishing target in the second leveling step is the precursor adhesive layer 31. As the slurry 210, a slurry that can remove the adhesive but cannot remove Cu (metal material) of the wiring portion 24 may be used. Further, the leveling apparatus 200 polishes the precursor adhesive layer 31 by setting the leveling conditions, such as the contact pressure of the slurry 210 with respect to the precursor substrate PW, rotational speed, and the like, to be different from the leveling conditions of the first leveling step.

For example, the contact pressure, or the rotational speed, or both of the slurry 210 of the second leveling step is set to be lower than the contact pressure, the rotational speed, or both of the slurry 203 of the first leveling step. Of course, in the second leveling step, both the contact pressure and the rotational speed can be set to be lower than the contact pressure and the rotational speed of the first leveling step. Thus, the adhesive layer 32, which is flush (leveled) with the wiring portions 24, can be formed in a favorable manner without damaging the wiring portions 24 in the second leveling step.

By performing the above steps up to the second leveling step, the substrate bonding method can produce the substrate W having the bonding surface S at which the wiring portions 24 and the adhesive layer 32 are continuous to be flush with each other. The adhesive layer 32 of the substrate W has a thickness T (e.g., 100 nm) corresponding to the thickness of the original upper layer 27. In the final bonding step (S6 of FIG. 3), two substrates W each formed by the above-described steps are transported to the bonding apparatus 100 (see FIG. 2), and a bonded substrate JW is produced by the bonding apparatus 100.

As illustrated in FIG. 1A, the bonding apparatus 100 includes a lower chuck 101 configured to hold a first substrate W1 on the lower side in the vertical direction, and an upper chuck 102 configured to hold a second substrate W2 on the upper side in the vertical direction in a processing chamber that is not illustrated. Further, the bonding apparatus 100 includes a striker mechanism 103 that presses down the second substrate W2 at the center of the upper chuck 102.

The bonding apparatus 100 allows the first substrate W1 and second substrate W2 to face each other in the vertical direction, and presses down the second substrate W2 using the striker mechanism 103 of the upper chuck 102 to drop the second substrate W2 against the first substrate W1. Thus, bonding between the first substrate W1 and the second substrate W2 progresses from the center toward the outer edge. In the bonding step, the opposing adhesive layers 32 between the wiring portions 24 are adhered to each other as illustrated in FIG. 1B, thereby forming a bonded substrate JW in which the first substrate W1 and the second substrate W2 are bonded together.

As described above, the substrate bonding method according to the present embodiment can bond two substrates W with each other with a high bonding strength because the adhesive layer 32 is provided between the wiring portions 24 in each substrate W. In particular, the adhesive layer 32 is formed thin, as the adhesive layer 32 is stacked on the underlying layer 26. Thus, each substrate W and the bonded substrate JW can avoid collapse of the wiring portions 24 and can reduce residual gas included in the adhesive as much as possible. Further, each substrate W and the bonded substrate JW can significantly reduce a thermal contraction of the adhesive layer 32 because of the thin adhesive layer 32 so that the occurrence of damage, such as cracks or the like, can be minimized.

The substrate bonding method and bonded substrate JW according to the present embodiment are not limited to the above embodiment, and various modifications can be made. For example, in the substrate bonding method, the upper layer 27 may remain on the underlying layer 26 without removing the entire upper layer 27 in the upper-layer removal step. Even in this case, the remaining upper layer 27 can be covered with the adhesive layer 32 formed in the sequential adhesive application step and the second leveling step so that a flat bonding surface S can be obtained.

### Second Embodiment

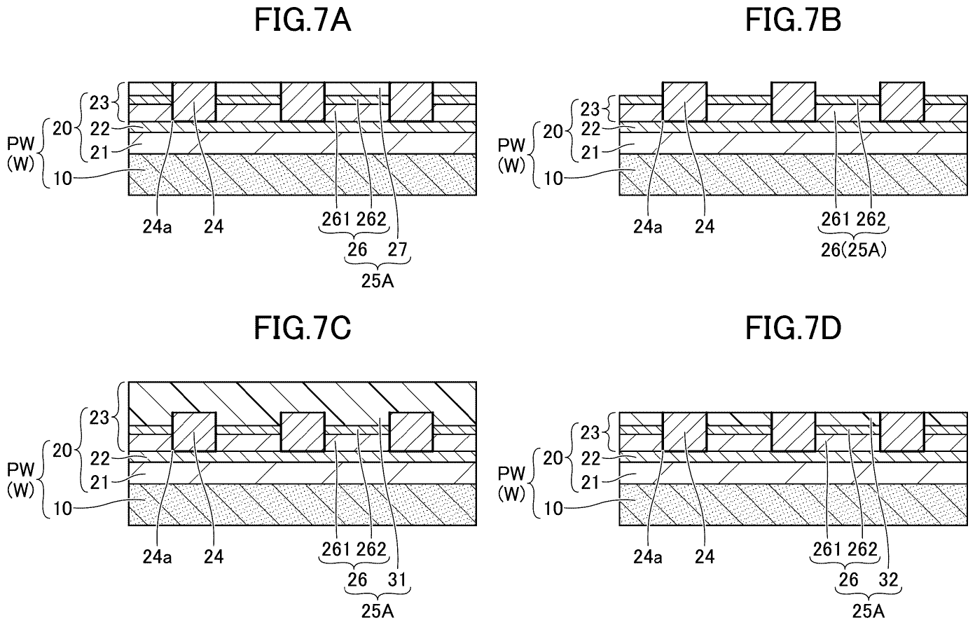

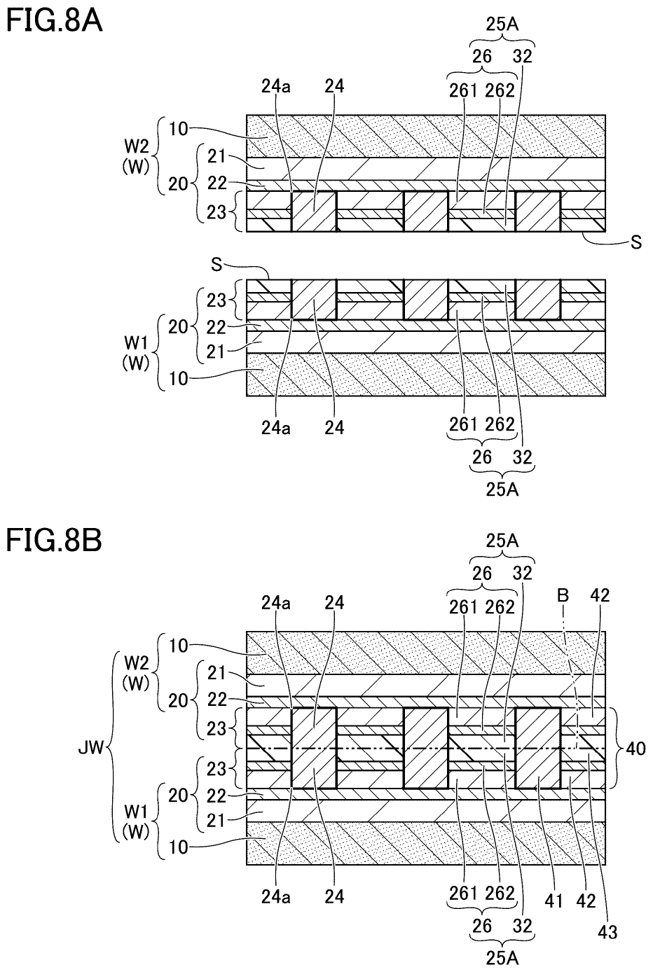

In the substrate bonding method according to the second embodiment illustrated in FIGS. 7A to 7D and FIGS. 8A to 8B, a stack structure of the insulating stack portion 25A of the substrate W before bonding is different from the stack structure of the insulating stack portion 25 according to the first embodiment. Specifically, as illustrated in FIG. 7A, the insulating stack portion 25A of the precursor substrate PW is formed as a three-layer structure in which two underlying layers 26 (a first underlying layer 261 and a second underlying layer 262) and one upper layer 27 are stacked.

The first underlying layer 261 constitutes a base of the insulating stack portion 25A (interlayer insulation film). As the first underlying layer 261, for example, a SiO₂ film or a SiOC film can be used.

The second underlying layer 262 is, for example, a layer formed so that a resultant insulating stack portion 25A has a low dielectric constant, that is, a so-called low-K layer. As the second underlying layer 262, a silicon carbonitride film (SiCN film) can be used. Note that a SiCN film may be also used as the second insulating layer portion 22 in the substrate W (precursor substrate PW).

Further, the upper layer 27 is a layer portion to be replaced with an adhesive layer 32. As the upper layer 27, any film that ensures etching selectivity with respect to the second underlying layer 262 can be used. For example, as the upper layer 27, a SiO₂ film or the like can be used as in the first embodiment.

Even with the precursor substrates PW each having the above insulating stack portion 25A, a bonded substrate JW, in which the two substrates W are strongly bonded to each other, can be produced by performing the same steps as in the substrate bonding method according to the first embodiment. Specifically, also in the substrate bonding method according to the second embodiment, a substrate providing step (step S1), a first leveling step (step S2), an upper-layer removal step (step S3), an adhesive application step (step S4), a second leveling step (step S5), and a bonding step (step S6) are performed in this order as illustrated in FIG. 3.

As illustrated in FIG. 7A, the wiring portions 24 and the upper layer 27 at the surface of the precursor substrate PW are leveled in the first leveling step. As illustrated in FIG. 7B, the upper layer 27 is removed while leaving the second underlying layer 262 of the precursor substrate PW in the upper-layer removal step. As illustrated in FIG. 7C, an adhesive is applied onto the surface of the precursor substrate PW to form a precursor adhesive layer 31 in the adhesive application step. As illustrated in FIG. 7D, the precursor adhesive layer 31 is polished to form a bonding surface S at which the wiring portions 24 and the adhesive layer 32 are leveled in the second leveling step. Thus, the substrate bonding method can produce the substrate W in which the adhesive layer 32 is disposed on the second underlying layer 262.

Therefore, as illustrated in FIG. 8A, the bonding surface S of the first substrate W1 and the bonding surface S of the second substrate W2 are arranged to face each other, and the second substrate W2 is dropped to form a bonded substrate JW in which the first substrate W1 and the second substrate W2 are bonded together in the bonding step. The adhesive layer 32 of each substrate W can bond two substrates W to each other with a high bonding strength.

In particular, the conductive bonded layer portion 40 of the bonded substrate JW is formed by bonding the adhesive layers 32 each formed on a corresponding underlying layer of the two underlying layers 26, and therefore the substrates W can be bonded together while insulating between the wiring portions 24 at a sufficiently low dielectric constant. Since the adhesive layer 32 can be formed thin because of the two underlying layers 26, the bonded substrate JW can further facilitate inhibition of collapse of the wiring portions 24, inhibition of a gas of the adhesive layer 32, reduction in thermal contraction, and the like.

The technical concepts and effects of the present disclosure described through the above embodiments will be described hereinafter.

The first embodiment of the present disclosure is a substrate bonding method for bonding two substrates W with each other, and the substrate bonding method includes: (a) providing of two substrates W each including wiring portions 24 and a stack portion (insulating stack portion 25), which includes an underlying layer 26 and an upper layer 27 that have etching selectivity in a thickness direction, disposed between the wiring portions 24; (b) forming of a surface at which the wiring portions 24 and the upper layer 27 are leveled; (c) removing of the upper layer 27 while leaving the underlying layer 26; (d) supplying of an adhesive to at least an area, from which the upper layer is removed, to form an adhesive layer (precursor adhesive layer 31) having a lower elastic modulus than the underlying layer 26; (e) forming of a bonding surface S at which the wiring portions 24 and the adhesive layer 32 are leveled; and (f) arranging of the bonding surface S of one of the two substrates W and the bonding surface S of the other one of the two substrates W to face each other and bonding of the two substrates with the adhesive layers 32, where (a), (b), (c), (d), (e), and (f) are performed in this order.

According to the above, in the substrate bonding method, the substrate W including the stack portion (insulating stack portion 25), in which the adhesive layer 32 is stacked on the underlying layer 26, disposed between the wiring portions 24 is obtained so that the two substrates W can be stably bonded to each other. Since the adhesive layer 32 allows a plasma treatment to be omitted at the time of bonding, reduction in conductivity of the wiring portions 24 or diffusion of the metal can be avoided. Further, the adhesive layer 32 can absorb some particles due to a low elastic modulus so that the opposing wiring portions 24 can be closely adhered to each other. In particular, collapse of the wiring portions 24 can be avoided because the underlying layer 26 is left in the stack portion when the upper layer 27 is removed, and generation of a gas and damage of the adhesive layer 32 itself can be minimized owing to the thin adhesive layer 32. Accordingly, the substrate bonding method can stably closely adhere the opposing wiring portions 24 and the opposing adhesive layers 32 to each other.

Further, the thickness of the adhesive layer 32 formed in (e) is thinner than the thickness of the underlying layer 26. Thus, the substrate bonding method can form a sufficiently thin adhesive layer 32, and the effect obtained by the thin adhesive layer 32 can be further enhanced.

Further, the thickness of the adhesive layer 32 formed in (e) is in the range of 20 nm to 150 nm. Thus, the substrate bonding method can form the adhesive layer 32 as thin as possible while ensuring the bonding strength of the adhesive layer 32.

Further, (d) further includes, after supplying the adhesive, heating of the adhesive to increase an elastic modulus of the adhesive. Thus, the substrate bonding method can perform the leveling of (e) on the adhesive layer (precursor adhesive layer 31) having a high elastic modulus, so that processability of the leveling of the adhesive layer 32 can be improved.

Further, a contact pressure, a rotational speed, or both of the slurry 210 used for leveling the adhesive layer 32 in (e) is set to be lower than a contact pressure, a rotational speed, or both of the slurry 203 used for leveling the wiring portions 24 and the upper layer 27 in (b). Thus, the substrate bonding method can readily level the adhesive layer 32 while minimizing damage of the wiring portions 24 when leveling is performed in (e).

Further, the underlying layer 26 is a SiOC film, and the upper layer 27 is a SiO₂ film. Thus, the substrate bonding method can stably remove the upper layer 27 while leaving the underlying layer 26 in (c).

Further, the underlying layer 26 includes multiple layers. Thus, the substrate bonding method can form interlayer insulation films having various properties, and can enhance the bonding strength between the two substrates with the thin adhesive layers 32.

Further, the multiple layers of the underlying layer 26 include a SiCN film. Thus, the substrate bonding method can form an interlayer insulation film having a low dielectric constant as the underlying layer 26.

A bonded substrate JW including two substrates W bonded to each other is provided. A region in which the two substrates are bonded includes wiring portions 41 and a stack portion (insulating stack portion 42), in which layers are stacked in a thickness direction, between the wiring portions 41. The stack portion includes a pair of underlying layers 26, each of which is disposed on a corresponding side of the both sides of the stack portion in the thickness direction, and an adhesive layer 43 that is interposed between the pair of the underlying layers 26 and has a lower elastic modulus than the underlying layers 26. The two substrates W are bonded to each other with the adhesive layer 43. Even in this case, the bonded substrate JW can stably bond the two substrates W with each other.

The substrate bonding method and the bonded substrate JW according to the present embodiment disclosed above are merely explanatory and are not restrictive. Various modifications and improvements can be made in the embodiments without departing from the scope and spirit of the appended claims. The features described in the above embodiments can have another configuration or may be combined together as long as such configuration or combination will not cause contradiction.

What is claimed is:

1. A substrate bonding method for bonding two substrates to each other, the substrate bonding method comprising:
(a) providing the two substrates, each substrate including wiring portions and a stack portion disposed between the wiring portions, the stack portion including an underlying layer and an upper layer that have etching selectivity in a thickness direction;
(b) forming a surface at which the wiring portions and the upper layer are leveled;
(c) removing the upper layer while leaving the underlying layer;
(d) supplying an adhesive to at least an area, from which the upper layer is removed, to form an adhesive layer having a lower elastic modulus than the underlying layer;
(e) forming a bonding surface at which the wiring portions and the adhesive layer are leveled; and
(f) arranging the bonding surface of one of the two substrates and the bonding surface of the other one of the two substrates to face each other and bonding the two substrates with the adhesive layers,
wherein (a), (b), (c), (d), (e), and (f) are performed in order as mentioned.

2. The substrate bonding method according to claim 1,
wherein a thickness of the adhesive layer formed in (e) is thinner than a thickness of the underlying layer.

3. The substrate bonding method according to claim 2,
wherein the thickness of the adhesive layer formed in (e) is in a range of 20 nm to 150 nm.

4. The substrate bonding method according to claim 1,
wherein (d) further includes, after supplying the adhesive, heating the adhesive to increase an elastic modulus of the adhesive.

5. The substrate bonding method according to claim 1,
wherein a contact pressure, a rotational speed, or both of a slurry used for leveling the adhesive layer in (e) is set to be lower than a contact pressure, a rotational speed, or both of a slurry used for leveling the wiring portions and the upper layer in (b).

6. The substrate bonding method according to claim 1,
wherein the underlying layer is a SiOC film, and the upper layer is a SiO₂ film.

7. The substrate bonding method according to claim 1,
wherein the underlying layer includes multiple layers.

8. The substrate bonding method according to claim 7,
wherein the multiple layers of the underlying layer include a SiCN film.

9. A bonded substrate comprising:
two substrates bonded to each other,
wherein a region in which the two substrates are bonded includes wiring portions and a stack portion, in which layers are stacked in a thickness direction, between the wiring portions, and
wherein the stack portion includes a pair of underlying layers, each of the underlying layers being provided at a corresponding side of both side of the stack portion in the thickness direction, and an adhesive layer that is interposed between the pair of underlying layers and has a lower elastic modulus than the underlying layers, where the two substrates are bonded by the adhesive layer.
